(19) United States
(12) Patent Application Publication
(10) Pub. No.: US 2008/0210965 A1
(43) Pub. Date: Sep. 4, 2008

(54) Light-emitting diode incorporation the packing nano particules with high refractive index

(76) Inventor: Chuan-Yu Hung, Jhongli City (TW)

Correspondence Address: Chuan-Yu Hung, No. 5-97, Guoling Village, Jhongli City, Taoyuan County, 320, TW

(21) Appl. No.: 11/973,602

(22) Filed: Oct. 9, 2007

(30) Foreign Application Priority Data
Oct. 11, 2006 (TW) 095137272

(51) Int. Cl. H01L 33/00

(52) U.S. Cl. 257/98; 438/29; 257/E33.067

(57) ABSTRACT

Light-emitting diode packages with very high light extraction efficiency are disclosed. The packages utilize the intrinsically optically transparent nano particles with high refractive index, by the correct way of homogeneous packing, or adding additional transparent substance in the interspaces among the nano particles furthermore, to form a nano light-extracting layer with high refractivity which contacts optically with the diode surface to extract the light. By this method, because the refractive index difference between the light-extracting layer and the diode crystal turns to be small, the critical internal total reflection angle of the light on the interface increases much, it means large reduction on the internal total reflection of the light. Then the light extraction efficiency of the package can be increased significantly.

### BACKGROUND OF THE INVENTION

1. Field of the Invention

This invention relates to a light-emitting diode package, more particularly, this invention relates to a light-emitting diode package incorporating the transparent nano particles with high refractive index.

2. Description of the Prior Art

With many advantages, the applications for light-emitting diode (LED) has continue to grow in recent years. A major challenge for the LED package developers is to achieve high photometric efficiency, especially for high power LED in general illumination application.

The luminescence of LED is resulted from that epitaxy emitting layer on LED chip can convert electric energy into optical energy and emits lights out through the transparent encapsulant material and finally into the atmosphere. But actually a major portion of lights can not go out. FIG. 1 illustrates the three possible paths of lights traveling from the higher refractive index media 11 into the one with lower refractive index 4, wherein, the refractive index nₒ is greater than nₑ. If the incidence angle θ is greater than the critical total reflection angle θc, the light L will totally reflect back to media 11 by the same angle instead of refracting into media 4, i.e. the light L can not penetrate media 4. The lights which can refract and penetrate are limited to the one with incident angle smaller than θc, i.e. the one inside the cone with a cone angle θc. Furthermore, by the Snell's Law, sin θc=nₑ/nₒ, if nₒ is much greater than nₑ, θc approaches zero, only little amount of light can go out.

FIG. 2 illustrates the prior LED package structure. The LED die 1 is traditionally bonded and electrically wire-connected 23 to the carrier body 21 and conducting metal 22 of the prior package carrier 2. The prior transparent encapsulant 4 encapsulates outside the LED die 1. The lights emitted by the die 1 travel through the transparent encapsulant 4 into atmosphere. Please refer to the Table which lists the

| LED Materials | RI | Encapsulants | RI | Oxides | RI | Oxides | RI | Compounds | RI |
|---|---|---|---|---|---|---|---|---|---|
| Blue LED GaN | 2.4 | Epoxy | 1.5 | TiO₂ Rutile | 2.75 | ZrO₂ | 2.3 | GaP | 3.2 |
| Sapphire substrate | 1.77 | Silicone | 1.42 | TiO₂ Anatase | 2.55 | ZnO | 2.0 | GaN | 2.4 |
| GaN substrate | 2.4 | (Air) | 1.0003 | SrTiO₃ | 2.5 | SnO | 2.0 | AlN | 2.2 |
| Green LED GaP | 3.2 | | | BaTiO₃ | 2.4 | Sb₂O₅ | 1.95 | ZnS | 2.37 |
| Red LED GaAs | 3.4 | | | | | Al₂O₃ | 1.77 | SiC | 2.65 |

refractive indices of related material. Because the refractive indices of the LED die crystal (such as blue LED epitaxy layer GaN:2.4, its Al₂O₃ substrate:1.77, red LED epitaxy layer GaAs:3.4) are all much greater than the transparent encapsulant's (such as silicone rubber:1.4, epoxy resin:1.5). Most of the lights emitted by LED epitaxy layer result in internal total reflection (for example, the θc is only 39° for blue chip 11 and epoxy resin encapsulant 4) on the interface due to the large refractive index difference. Because of the parallel top bottom interfaces of the epitaxy layer, after several total reflections the lights finally become the heat energy. This will further reduces the lifetime of the device besides performing the very low light extraction efficiency of the LED. One method just intended to improve this drawback by a transparent optical solid element bonded to the LED chip surface by high temperature treatment is previously discussed in U.S. Pat. Nos. 7,053,419 and 7,064,355 enclosed herein for reference. And U.S. Pat. Nos. 6,870,311 & 7,083,490, Japan Pat. Nos. 2004-15063, 2007-51053, 2007-70603, 2007-204354 disclose a method to increase the refractive index of the encapsulants by nano particles dispersed in the encapsulants to increase the light extraction efficiency of LED. And Taiwan Pat. No. 1220067 also relates to a method to enhance the encapsulant by nano particles dispersed. They are necessarily enclosed herein for references.

### SUMMARY OF THE INVENTION

The present invention provides a manufactuable method and structure to achieve a higher light extraction efficiency of LED packages than the low efficiency of prior LED due to the low refractive index encapsulant.

For the purpose, the invented LED package utilizes the intrinsically optically transparent nano particles with high refractive index, by the correct way of homogeneous packing, to form a nano light-extracting layer with high refractivity, which contacts optically with the chip surface to extract the lights.

According to another embodiment of this invention, the nano light-extracting layer is made of nano composite material which forms by the intrinsically optically transparent nano particles with high refractive index, packing homogeneously in additional transparent substance. According to another fabricating process for this invention, which includes the following steps: first a plastic transparent nano gel bulk with a curved top surface and a flat bottom surface forms by the nano sol, the gel bulk is removed to the top surface of the LED chip such that the two surfaces form an optical contact naturally, the gel bulk hardens to be the nano light-extracting layer.

By this structure, because the refractive index difference between the light-extracting layer and the diode crystal turns to be smaller, the internal total reflection angle of the light on the interface increases much. It means reducing the internal total reflection of the light. Then the light extraction efficiency of the package can be increased significantly.

The accompanying drawings are included to provide a further understanding of this invention.

### BRIEF DESCRIPTION OF THE DRAWINGS

FIG. 1 illustrates the possible paths of light traveling from the higher refractive media into the lower one;

FIG. 2 illustrates the prior LED package structure;

FIG. 3 illustrates the flip-chip LED structure of this invention incorporating the nano TiO2 light-extracting layer;

FIG. 4 illustrates the LED structure of this invention incorporating the nano TiO₂ composite light-extracting layer encapsulated by epoxy resin;

FIG. 5 illustrates the LED structure of this invention incorporating the nano ZrO₂ composite light-extracting layer encapsulated by silicone rubber;

FIG. 6 illustrates the LED structure of this invention incorporating the nano light-extracting layer by the transparent nano gel bulk;

FIG. 7 illustrates the LED structure of this invention incorporating the nano light-extracting layer with half sphere surface.

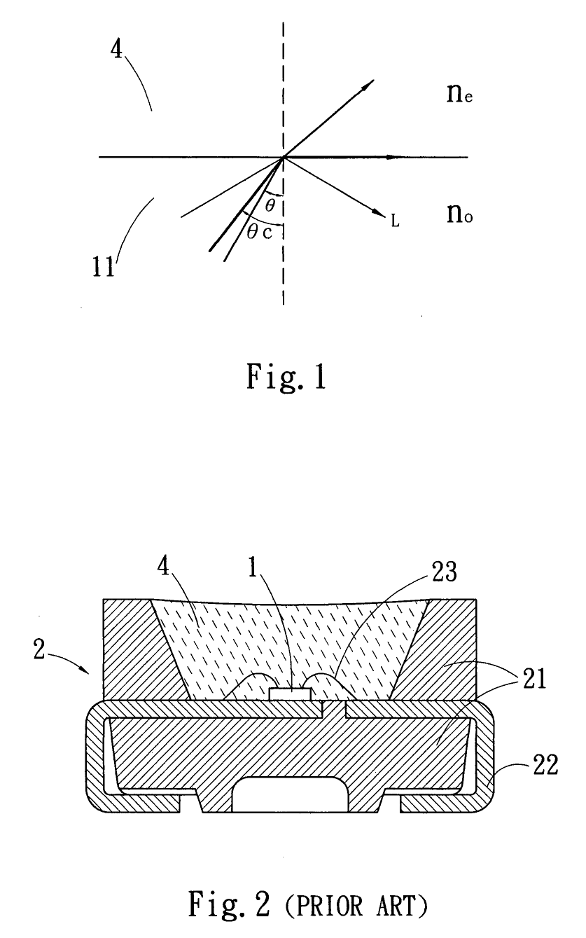

### DETAILED DESCRIPTION OF THE PREFERRED EMBODIMENTS

The refractive index of prior encapsulant for LED package is around 1.42˜1.50. The increase of the refractive index of the encapsulant by dispersed nano particles in the reference patents is only 0.1˜0.2. This invention is to improve the drawback of the encapsulant with low refractive index.

First of all, from the knowledge of basic optics, the scattered degree of visible light by mono-dispersed transparent particles depends on the particles size, besides positively relating to the refractive index difference between the particle and its environment. If the particles size is equal to half the light wave length (400˜700 nm), the scattering degree is optimum. As the particles size decreases, the scattering approaches zero by exponentiation. And the appearance of the system tends to transparency from white color, in another word, the particle size of the non-scattering and transparency showing is set around generally defined nano size. Moreover, considering the undispersed nano particles, although their particles size is so small, they will agglomerate due to the van der Waals force between the particles. And the size of the second agglomerated particles may set around the visible light wave length range or larger, so they will still scatter light and become white color, i.e. only mono-dispersed or homogeneous packing nano particles are transparent to visible light.

For instance, general micron order powders scatter light. If the particle size is smaller than 100 nm, such as 30 nm, and they disperse uniformly in water, the so-called aqueous sol scatters light very slightly and appears almost transparent. After the water content is slowly removed, the dispersed nano particles pack homogeneously by themselves to form a strong transparent solid block, no longer shows of the appearance and properties like general powder. Meanwhile, the dispersed nano particles pack homogeneously within specific transparent solid substance to form a so-called nano composite material is as the same condition.

In addition, the apparent refractive index of the homogeneous packing nano particles composite is equal to the sum of the refractive indices of the nano particle and its environment multiplied by their volume fraction respectively.

Base on the foregoing concepts, this invention utilizes the intrinsically optically transparent nano particles with high refractive index, by the correct way of homogeneous packing, or adding additional transparent substance in the interspaces among the nano particles furthermore, to form a nano light-extracting layer with high refractivity which contacts optically with the diode to extract the light.

Specific embodiments of the present invention will now be described, by way of example only, with reference to the accompanying drawings.

### The First Embodiment

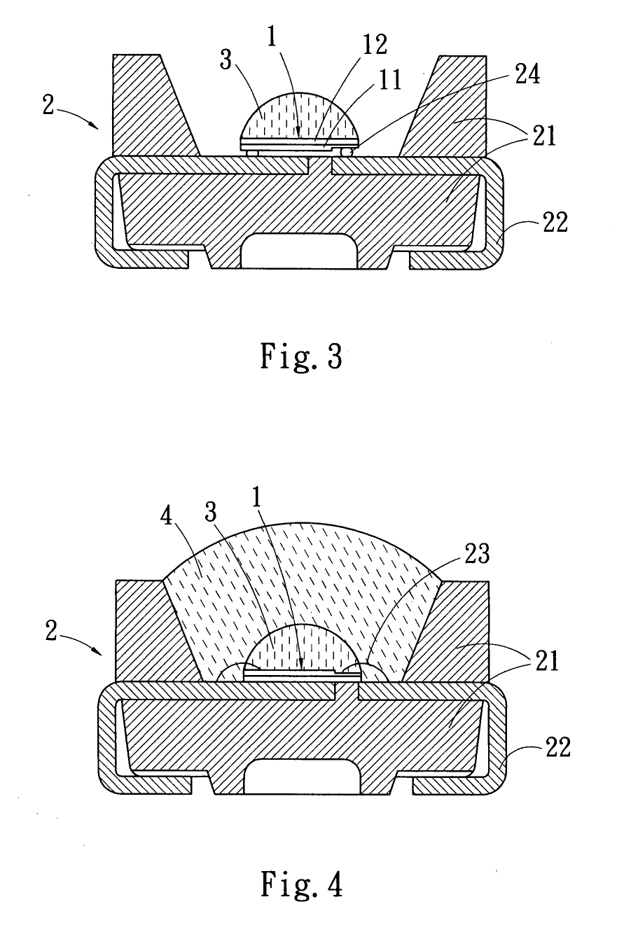

FIG. 3 illustrates a prior art of flip-chip mounting LED. So-called flip-chip means to turn the chip upside down to make the bottom 12 (transparent epitaxy sapphire substrate 12) be an emitting surface. By this mounting the substrate 12 transmits lights emitted from the epitaxial layer 11 to the prior encapsulant (not shown in FIG. 3) and finally into the atmosphere.

With reference to FIG. 3, first a high power blue LED chip 1 is mounted on a carrier 2 by flip-chip. And a for-sale 5 wt % transparent anatase phase nano TiO₂ aqueous sol with average particle size of 10 nm and with a dispersed treatment by the eletrostatic repulsion method is prepared. After evaporating a portion of the water content slowly, it condenses to a gel with 40 vol % TiO₂ particles. Meanwhile a vacuum is set to de-bubble. Then a small amount of this gel is dispensed on this flip-chip 1 top surface by gel-dispensing method. After slowest drying about 72 hours, the nano particles in this gel contact with each other and generate some strength to form a nano light-extracting layer 3 with a naturally curved surface, shown in FIG. 3 by nano TiO₂ particles packing homogeneously. The packing density of nano particles is measured by Archimedes method and 49 vol % density of the total nano layer volume is obtained. The apparent refractive index of the nano layer 3 is 1.76 almost the same as the epitaxy substrate 1.77. By this way, the lights emitted by the emitting layer through the substrate can totally travel into the nano light-extracting layer 3. Then the lights will run into atmosphere more easily by the curved surface of the nano layer 3. So the light extraction efficiency of LED is increased.

On the other side, a conventional mounting blue LED package is under consideration. By this way, the epitaxial GaN light-emitting layer 11 is the top surface having refractive index 2.4. With reference to FIG. 4, after the described nano light-extracting layer is finished by the same way, furthermore some prior encapsulant such as epoxy resin is pot on the nano layer 3 surface. By capillarity and vacuum treatment, the resin penetrates into the interspaces among the nano particles in the nano layer, and cures at 120° C. for one hour. By this way, the air in the interspaces becomes the epoxy resin. The apparent refractive index of the nano composite layer 3 increases up to 2.0, much close to GaN 2.4. Meanwhile, more amount of epoxy 4 may be controlled optionally to encapsulate the nano layer 3 and the LED chip 1. Therefore by way of more refractive index steps from inside to ambience, it's apt to reduce the Fresnel Loss. Then the light extraction efficiency of LED can be increased further.

### The Second Embodiment

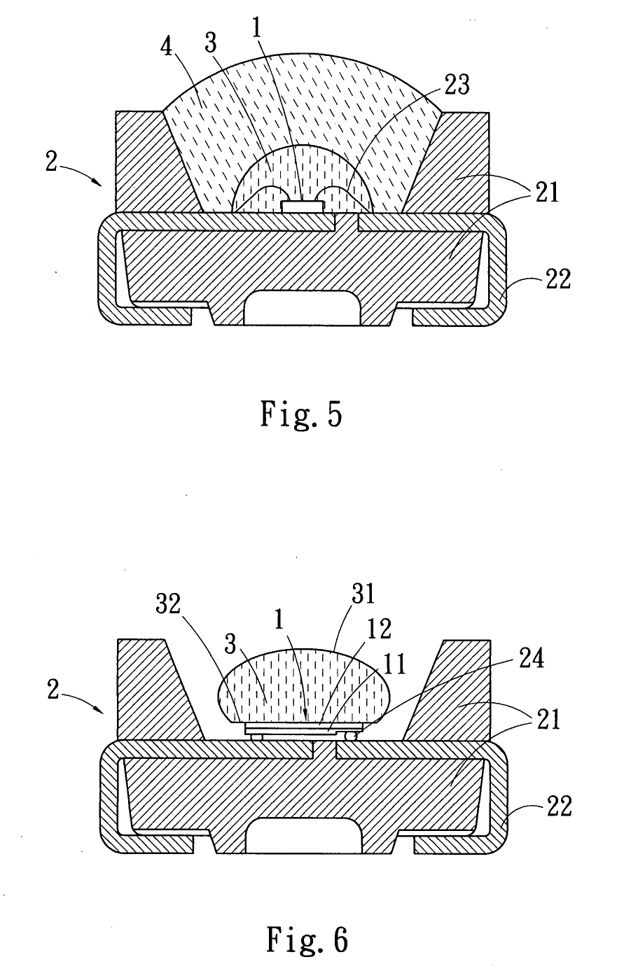

According to a traditional mounting low power LED package, first a LED die 1 is mounted on a carrier 2 with reference to FIG. 5. And a for-sale 10 wt % transparent nano ZrO₂ aqueous sol with average particle size of 20 nm and with dispersed treatment is prepared. And a high purity 75 wt % potassium silicate (K₂SiO₃) aqueous solution is also prepared. The two liquids are stirred and mixed by 40% ZrO₂ vs. 60% K₂SiO₃ volume fraction. After evaporating a portion of the water content, it condenses to a gel with workable viscosity. Meanwhile a vacuum is set to de-bubble. Then a small amount of this gel is dispensed around this LED die 1 by gel-dispensing method to encapsulate the die 1 and the electric connecting wires 23. After drying slowly, the gel forms a nano composite light-extracting layer 3 with a naturally curved surface, shown in FIG. 5 by nano ZrO₂ particles packing homogeneously within K₂SiO₃ solid. The density of the nano light-extracting layer is measured by Archimedes method and the relative density of nano ZrO₂ particles is 40% to the total nano layer volume, just the same as the mixing recipe. The apparent refractive index of the nano layer is 1.86 much larger than the prior encapsulant's. By this way, the lights emitted by emitting layer can mostly travel into the nano light-extracting layer 3. Then the lights will run into atmosphere more easily by the curved surface of the nano layer 3. So the light extraction efficiency of LED is increased.

In addition, the prior encapsulant such as silicone rubber 4 may be pot on the nano layer 3 surface to encapsulate the nano layer 3 and the LED die 1. Therefore by way of more refractive index steps from inside to ambience, it's apt to reduce the Fresnel Loss. Then the light extraction efficiency of LED can be increased furthermore.

### The Third Embodiment

According to a traditional mounting low power LED package, first a LED die 1 is mounted on a carrier 2 with reference to FIG. 5 again. And some for-sale rutile phase nano TiO₂ powder (without surface treatment) with average particle size of 15 nm are first finished mono-dispersion in n-Butyl Alcohol (NBA) by the dispersing method named surface grafting by common use methoxyl silane couple agent. Base on the volume fraction of 30% TiO₂:15% epoxy A:55% NBA, the nano TiO₂ NBA sol is stirred and mixed with prior LED encapsulant epoxy A resin, such that the nano particles are well dispersed in epoxy and NBA solution ready for use. By the volume ratio of 1 epoxy A:1 hardening agent, it is stirred and mixed with epoxy B hardening agent before fabrication. Therefore, at this time the volume ratio of nano TiO₂ vs. surface grafted couple agent vs. total resins is 1:1:1. After evaporating a portion of the NBA, it condenses to a gel containing about 20 vol % NBA with workable viscosity. Meanwhile a vacuum is set to de-bubble. Then some of this gel is dispensed on this LED die 1 by gel-dispensing method to encapsulate the die 1 and the electric connecting wires 23. After drying NBA slowly, the gel shrinks by 16 vol % and forms a hard gel bulk with no fluidity by the liquid epoxy resin filling in the interspaces among the homogeneous packing of nano TiO₂ particles (not the liquid gel by the nano TiO₂ particles dispersing in liquid epoxy resin). The resin cures at 120° C. for one hour. Then the gel forms a nano solid composite light-extracting layer 3 shown in FIG. 5 by the solid epoxy resin filling in the interspaces among the homogeneous packing of nano TiO₂ particles. The density of the nano light-extracting layer is measured by Archimedes method and the relative density of nano TiO₂ particles is 32% to the total nano layer volume, the overall volume fraction of nano particles including the couple agent layer of surface coating is 64%, and the volume fraction of the epoxy is only 32%, which results in about 4 vol % air void, Anyway, with comparing to the dispersing structure, the packing structure has a higher particles density. The apparent refractive index of the nano layer is 1.88 much larger than the prior encapsulant's. By this way, the lights emitted by emitting layer can mostly travel into the nano light-extracting layer 3. And the lights will run into atmosphere more easily by the thick nano layer 3. So the light extraction efficiency of LED is increased. The overall photometric efficiency increases 10˜40% generally in experiment results.

### The Fourth Embodiment

From another aspect, in term of the fabricating process for this invention, when the solvent evaporates rapidly, the nano light-extracting layer will generates certain degree of internal stress due to three dimension shrinkage itself plus the drag of the LED chip. To prevent this problem, this invention also discloses an additional practical fabricating process method. One embodiment of the method includes such steps: first a LED chip 1 is mounted on a carrier 2 by flip-chip with reference to FIG. 6. And the transparent dispersed nano aqueous sol in the first embodiment is prepared. After condensing to a gel with workable viscosity, about 0.01 CC of this gel is dispensed on a smooth flat surface of plastics by gel-dispensing method. The water content evaporating is controlled slowly such that the dispensed gel shrinks freely in three dimension without any drag. Just before the moisture evaporates entirely, it forms a plastic transparent nano gel bulk with a curved top surface 31 and a flat bottom surface 32 larger than LED chip 1 surface. Then the gel bulk is removed to the top surface of the mounted LED chip 1. By its plastic property, the two surfaces can form optical contact naturally. After drying slowly, the gel bulk forms the nano light-extracting layer 3.

In a related embodiment, the transparent dispersed nano gel in the third embodiment is dispensed on the flat surface. But the solvent can evaporate entirely. Due to the function of the liquid epoxy resin in the nano gel content, it still forms a plastic transparent nano gel bulk. After the nano gel bulk is removed to the top surface of the chip 1, the epoxy resin can be cured. Also the two surfaces form optical contact naturally and generate bonding strength. And the gel bulk forms the nano light-extracting layer 3.

By this way, because the nano light-extracting layer has finished most or total shrinkage before contacting the LED chip surface, the internal stress will be eliminated to prevent the reliability problem.

In all the preferred embodiments, the light-emitting diode 1 and the package carrier 2 and the particles material in the nano layer 3 are not restricted to those indicated in the embodiments. In general, the LED chip may be blue light, green light, red light chip or other light chip or other invisible light chip. The carrier may be ceramic substrate, plastic substrate, metal substrate, dipping frame, molding potting frame etc. The nano particles may be made of transparent metal oxide or semiconductor compound with high refractive index such as titanium oxide, zirconium oxide, tin oxide, antimony oxide, aluminum oxide, barium titanate, strontium titanate, gallium phosphide, gallium nitride, aluminum nitride, zinc sulfide, silicon carbide etc. and their combination, or other material on condition that it is substantially transparent to the light wave length emitted by the corresponding chip, and the refractive index must be higher than 1.65 to obtain minimum efficacy, and the average particles size must be less that 100 nm.

After the foregoing embodiments are described, here are supplemental explanations, in this invention the nano particles with high refractive index is the essential factor which is indispensable for the intended purpose. If a transparent substance exists in the interspaces among the nano particles, that can increase the refractive index, but a transparent substance is not absolutely necessary. Just as the homogeneous location of the nano particles is indispensable to perform the sufficient transparency and contribute the refractive index, but the dispersing process is only one of the paths to achieve the homogenous packing. The dispersion itself is not absolutely necessary.

The term “packing” herein is generally used to describe the status of traditional ceramic powder. Herein a further definition is: almost all the nano particles in a system directly or indirectly contact with others and keep a regular or unregulated arrangement status by the smallest distance as the agglomerate particles, due to the attractive net force between particles, and the thermal vibration of solvent media molecular is not enough to overcome the attractive force and particles gravity to make the Brownian movement of particles, or due to the reduced amount of solvent media such that the particles no longer have sufficient space to move relatively, both of them make the system in macro scope form as a gel bulk, a soft plastic bulk or even a hard solid bulk with little or no fluidity, unless some external force applies on particles. And furthermore, the most condensed packing is that particles arrange in a regular symmetrical mode by themselves, such as “Face Center Cubic (FCC)” packing. This is the so-called “Self-assembly” of nano particles in nano technology field. They are different from the status of particles “dispersing” in solvent media, which is that the nano particles are not contacting with others and ability of any random relative motion. The system in macro scope is a liquid phase, the distance between particles changes in according to the increase of solvent media volume.

In this invented structure, the described differences between “packing” and “dispersing” result in several advantages, one is that the light scattering degree by packing particles is much smaller, the transparency of the light-extracting layer is much higher, and very sensitive to the tiny variation of packing density. The other is that the density of packing particles is relatively higher, the refractive index of the light-extracting layer is relatively larger, the increase of the LED light extraction efficiency becomes obvious. The highest volume fraction of nano particles which the well-known dispersed nano sol can achieve under the limitation of workable viscosity is only about 8˜14% due to the unique gelation property of nano particles. Accordingly, this leads to a gain of refractive index of the LED encapsulant by only around 0.08˜0.17. Without the improvement of increasing particles density and refractive index by the structure of packing particles, its application will be certainly restricted.

Some supplemental methods to enhance this invention are disclosed herein. According to the spirit of this invention, in order to increase the light extraction efficiency of LED, besides choosing the available nano particles with highest refractive index, their packing density in the layer must also be increased. For this purpose, two or more kinds of particles with different particle sizes can be blended in the foregoing embodiments in order to obtain higher packing density. For instance, two nano TiO₂ particles with average particle sizes 20 nm, 5 nm are selected to form the nano light-extracting layer. The packing density increases about 10% after drying. Due to the higher refractive index of the nano light-extracting layer, the light extraction efficiency of LED is increased accordingly.

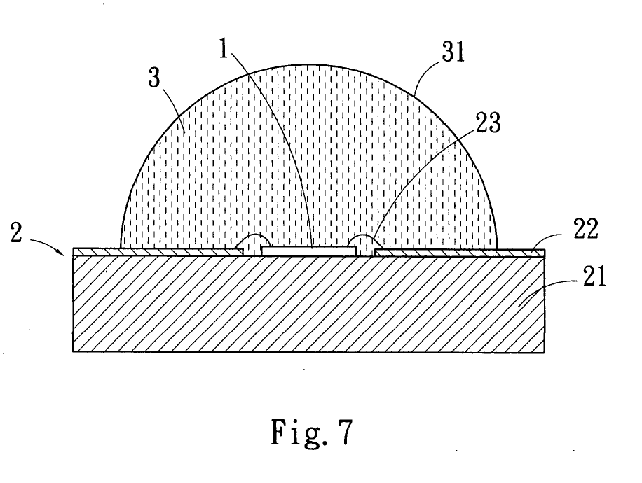

Moreover, as shown in FIG. 7, the interface 31 between the nano layer and the atmosphere can form as an approximate half of sphere surface 31 with a proper diameter, for instance, a diameter larger than three times the edge length of the square chip, meanwhile the light-emitting diode chip 1 locates on the sphere center. By this way, the light emitted from the chip into the nano layer can totally penetrate the surface 31 in approximately vertical direction without any total reflection to be absorbed finally. Therefore, the light extraction efficiency on the interface between the nano layer and the atmosphere can be increased further.

Herein disclose two methods to enhance the interface between the nano layer and the atmosphere. One of them is to form the surface 31 with a periodical texture (not shown) by the period about visible light wave length, i.e. the photonic crystal. structure, by photo mask and solvent dissolving process. The other is to form the surface 31 with a roughness (not shown) about microns to hundreds of microns order by random solvent dissolving, etching or molding process. Either of them can increase the light fraction into the atmosphere. The light extraction efficiency on the interface between the nano layer and the atmosphere can also be increased further.

To deal with the build-in phosphor for white LED illumination application, the prior phosphor may just be added into the internal central portion around the chip or the external space of the nano layer to transfer the light wave length emitted by the LED chip. The increasing function of the light extraction efficiency will remain the same.

In addition, from the related knowledge of photo catalyst, certain nano oxides possess the photo catalyst property. i.e. It is apt to absorb the ultraviolet and decompose the surrounding organic and turn yellow color. To avoid this effect, generally the nano oxides particles may be coated with some other neutral substance to form so-called core-shell structure, for example, the core-shell particles by coating the nano TiO₂ particles in this invention with Al₂O₃. Such surface-modified nano TiO₂ is not only easier to disperse but also without the drawback of decomposing the surrounding organic.

In conclusion, the LED package in this invention utilizes the intrinsically optically transparent nano particles with high refractive index to form a nano light-extracting layer with high refractivity to extract the light. The light extraction efficiency can be increased significantly.

It is apparent that various modifications and variations can be made to this invention without departing from the scope or spirit of the invention. The description is illustrative of the invention and is not to be construed as limiting the invention. It is intended that the present invention cover modifications and variations of this invention, and they fall within the scope of the following claims and their equivalents.

What is claimed is:

1. A light-emitting diode package, comprising:
at least a light-emitting diode chip;
a carrier, providing the mechanical and electrical connection to said light-emitting diode chip;
a nano light-extracting layer, optically contacting to at least a portion of surface of said light-emitting diode chip;
characterized in:
that said nano light-extracting layer is made of at least nano particles packing homogeneously, with refractive index higher than 1.65 and average particle size less than 100 nm; said nano particles material is substantially transparent to the light wave length emitted by said chip.

2. A light-emitting diode package according to claim 1, wherein said nano particles are surface-modified or surface-grafted particles.

3. A light-emitting diode package according to claim 1, wherein said nano light-extracting layer further comprising the surface-grafting substance of said nano particles or another transparent substance in at least the partial interspaces among said nano particles.

4. A light-emitting diode package according to claim 1, wherein said nano light-extracting layer further comprising a transparent encapsulant layer with lower refractive index encapsulating outside said nano light-extracting layer and said light-emitting diode chip.

5. A light-emitting diode package according to claim 1, wherein said nano particles are blended by at least two kinds of nano particles with different average particle sizes.

6. A light-emitting diode package according to claim 1, wherein the interface between said nano light-extracting layer and the atmosphere forms as an approximate half of sphere surface with a proper diameter, meanwhile said light-emitting diode chip locates on the sphere center.

7. A light-emitting diode package according to claim 1, wherein the interface between said nano light-extracting layer and the atmosphere forms a surface with a periodical structure by the period about visible light wave length, i.e. photonic crystal structure.

8. A light-emitting diode package according to claim 1, wherein the interface between said nano light-extracting layer and the atmosphere forms a surface with a roughness about microns to hundreds of microns order.

9. A light-emitting diode package according to claim 1, wherein some phosphor is added in the internal central portion or the external space of said nano light-extracting layer to transfer the light wave length emitted by said light-emitting diode chip.

10. A light-emitting diode package according to claim 1, wherein said nano particles have core-shell structure. i.e. The surface and inner portion of the particle are made of different substances.

11. A light-emitting diode package according to claim 1, wherein said light-emitting diode chip is blue light, green light, red light chip or other light chip, or other invisible light chip.

12. A light-emitting diode package according to claim 1, wherein said carrier is ceramic substrate, plastic substrate, metal substrate, dipping frame, molding potting frame etc.

13. A light-emitting diode package according to claim 1, wherein said nano particles are made of transparent metal oxide or semiconductor compound with high refractive index such as titanium oxide, zirconium oxide, tin oxide, antimony oxide, aluminum oxide, barium titanate, strontium titanate, gallium phosphide, gallium nitride, aluminum nitride, zinc sulfide, silicon carbide etc. or their combination.

14. A light-emitting diode package, comprising:
at least a light-emitting diode chip;
a carrier, providing the mechanical and electrical connection to said light-emitting diode chip;
a nano light-extracting layer, optically contacting to at least a portion of surface of said light-emitting diode chip;
characterized in:
that said nano light-extracting layer is made of nano composite material which forms by at least nano particles with refractive index higher than 1.65 and average particle size less than 100 nm, packing homogeneously in a transparent substance; said nano particles material is substantially transparent to the light wave length emitted by said chip.

15. A light-emitting diode package according to claim 14, wherein the volume fraction of said nano particles in said nano light-extracting layer is higher than 25%.

16. A light-emitting diode package according to claim 14, wherein said transparent substance in said nano light-extracting layer is liquid phase or solid phase polymer, organic or non organic substance.

17. A fabricating process for light-emitting diode including the following steps:
a LED chip is prepared;
a dispersed nano gel with workable viscosity and made of intrinsically optically transparent nano particles with high refractive index is prepared;
certain amount of said nano gel is dispensed on a smooth flat surface, the solvent evaporates such that the dispensed gel shrinks freely to form a plastic transparent nano gel bulk with a curved top surface and a flat bottom surface;
said gel bulk is removed to the surface of said LED chip such that the two surfaces form optical contact naturally;
the gel bulk hardens to be the nano light-extracting layer on the emitting surface of said LED chip.

18. A fabricating process for light-emitting diode according to claim 17, wherein said dispersed nano gel contents a transparent resin of liquid phase.
